(19) United States
(12) Patent Application Publication
(10) Pub. No.: US 2009/0189159 A1
(43) Pub. Date: Jul. 30, 2009

(54) GETTERING LAYER ON SUBSTRATE

(75) Inventors: Darwin Enicks, Colorado Springs, CO (US); Mark Good, Colorado Springs, CO (US); John Chaffee, Colorado Springs, CO (US)

Correspondence Address: FISH & RICHARDSON P.C., PO BOX 1022, MINNEAPOLIS, MN, 55440-1022, US

(73) Assignee: ATMEL CORPORATION, San Jose, CA (US)

(21) Appl. No.: 12/020,930

(22) Filed: Jan. 28, 2008

(51) Int. Cl. H01L 29/04; H01L 21/322

(52) U.S. Cl. 257/63; 438/473; 257/E21.317; 257/E29.003

(57) ABSTRACT

Disclosed herein are devices, methods and systems for implementing gettering layers. Devices including gettering layers can be implemented such that a gettering layer doped with carbon, boron, fluorine or any other appropriate impurity is formed on a semiconductor substrate, a device layer is formed on the gettering layer, and a device region is formed in the device layer having a depth that maintains a distance in the device layer between the gettering layer and the device region.

### BACKGROUND

This specification relates to semiconductor devices.

Semiconductors are manufactured in highly controlled environments. Contaminants that are not controlled or isolated can introduce impurities in the semiconductors, and these impurities can reduce the yield of a semiconductor manufacturing process.

Gettering is a process to reduce or isolate the contaminants that are present in the semiconductor devices. Gettering removes impurities from the active circuit regions of a wafer to enhance the yield of circuit manufacturing. There are two general classifications of gettering—extrinsic and intrinsic. Extrinsic gettering employs external means to create damage or stress in the silicon lattice. These damaged and/or stressed regions trap impurities that migrate through a substrate. Extrinsic gettering can be done, for example, by laser ablation of a backside of a silicon wafer. Extrinsic gettering, however, can sometimes reduce manufacturing yield if the damage is too severe. Similarly, extrinsic gettering can become less effective due to annealing during normal process sequencing.

Intrinsic gettering creates impurity trapping sites through the formation of bulk micro-defects within the semiconductor substrate. These bulk micro-defects can be created by the growth of silicon oxide precipitates in the silicon wafer. The bulk micro-defects create stress regions that attract and trap contaminants. However, semiconductor manufacturers can receive semiconductor substrates from vendors that have varying concentrations of interstitial oxygen and vacancies that may limit the formation of bulk micro-defects. Additionally, the creation of bulk micro-defects in close proximity to the device layer can actually decrease yield, as impurities are thus collected in the device layer.

### SUMMARY

Disclosed herein are devices, methods and systems for implementing gettering layers. Devices including a gettering layer can be implemented such that a gettering layer doped with carbon, boron, fluorine or any other appropriate impurity is formed on a semiconductor substrate, a device layer is formed on the gettering layer, and a device region is formed in the device layer having a depth that maintains a distance in the device layer between the gettering layer and the device region.

Implementations may include one or more of the following features and/or advantages. The gettering layer can attract and trap contaminants so that the contaminants do not affect the performance of the device. Additionally, the gettering layer prevents diffusion of contaminants into the device region prior to the formation of bulk micro-defects. Further, gettering layers doped with carbon, boron, fluorine, or any other appropriate impurity prevents diffusion of oxygen into the device region. Still further, gettering layer formation is independent of the properties of the semiconductor substrate.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a block diagram illustrating an example device having a gettering layer.

FIG. 2 is a block diagram illustrating another example device having a gettering layer.

FIG. 3 is a flow chart illustrating an example process for manufacturing a device including a gettering layer.

Like reference numbers and designations in the various drawings indicate like elements.

### DETAILED DESCRIPTION

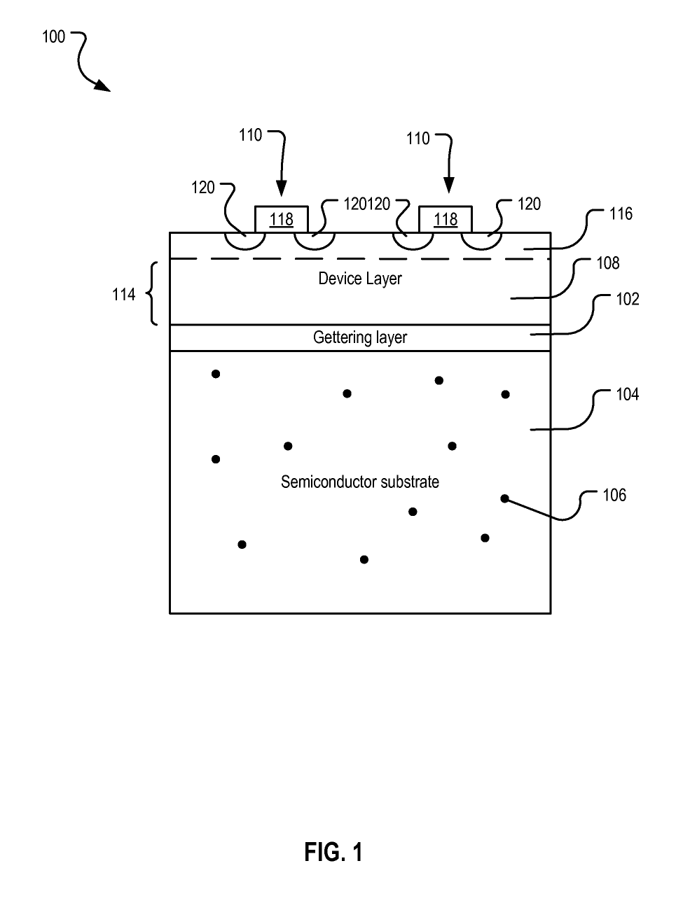

FIG. 1 is a block diagram illustrating an example device 100 having a gettering layer 102. The gettering layer 102 is formed on a semiconductor substrate 104. The semiconductor substrate 104 can be silicon, silicon germanium, silicon germanium carbide, germanium, germanium carbide, gallium arsenide, or any other appropriate semiconductor substrate (e.g., compounds having at least one group III element and at least one group V element (“III/V group”) or compounds having at least one group II element and at least one group VI element (“II/VI group”). Additionally, the semiconductor substrate 104 can be either an n-type or p-type substrate. Further, the semiconductor substrate 104 can have a thickness that ranges, for example, from 5 micrometers to at least 725 micrometers, however, thicker or thinner semiconductor substrates 104 can also be used.

In some implementations, bulk micro-defects 106 can be formed in the semiconductor substrate 104 during one or more annealing processes. The formation of the bulk micro-defects 106 varies based on the characteristics of the semiconductor substrate 104. For example, a semiconductor substrate 104 having low concentrations of interstitial oxygen, vacancies, or boron will yield low concentrations of bulk-micro-defects 106. The concentration of bulk micro-defects 106 in a semiconductor substrate 104 can also vary with the number of annealing processes that have been completed. Accordingly, a gettering layer 102 can be formed on the semiconductor substrate 104 to ensure that sufficient gettering is available.

The gettering layer 102 can be a layer formed from epitaxially grown silicon germanium, silicon germanium carbide, silicon carbide, germanium, germanium carbide, or any other appropriate compounds (e.g., selected from the III/V group or II/VI group.). The gettering layer 102 can be formed to have a thickness, for example, ranging from 3 nanometers to at least 500 nanometers, but other gettering layer thicknesses can be used. Additionally, the gettering layer 102 can be formed as a strained or partially strained gettering layer, depending on the doping material used. The gettering layer 102 can prevent contaminants from the semiconductor substrate 104 from entering a device layer 108 and/or a device region 116, or can gather contaminants introduced in the device layer 116 during manufacturing.

A device layer 108 is formed on the gettering layer 102. The device layer 108 can be formed from epitaxially grown silicon, silicon germanium, silicon germanium carbide, germanium, germanium carbide, silicon carbide, or any other appropriate compounds (e.g., compounds selected from the III/V group or II/VI group.). In some implementations, the device layer 108 has a reduced oxygen content that inhibits the formation of bulk micro-defects 106 in the device layer 108. The device layer 108 has a thickness that can range, for example, from 3 micrometers to 100 micrometers. This thickness range is for example purposes only and other device layer thicknesses can be used. The thickness of the device layer 108 will depend on the devices 110 that are being formed in the device region 116. For example, if a high voltage device is being formed in a device region 116 of the device layer 108, then the device layer thickness will be greater than that formed for a low voltage device.

The device layer 108 is formed having a thickness that maintains a distance 114 between the gettering layer 102 and the device region 116.

The device region 116 is the area within the device layer 108 where the semiconductor devices 110 are formed. The semiconductor devices 110 can, for example, be low voltage transistors or high voltage transistors, or other electrical devices that can be formed in the device layer 116. The semiconductor devices 110 have gates 118 formed on the device region 116. Additionally, the semiconductor devices 110 have doped regions 120 that define sources and drains for the semiconductor devices 110. The depth of the doped regions 120 depends on the concentration of dopants, implant energy, dopant species, and temperature/time product after introduction of dopant used to create the doped regions 120. Any one or a combination of these factors can result in larger and deeper doped regions 120. Therefore, a particular doped region 120, resulting from the combination of these factors, will define the required thickness of the device layer 108.

For example, a larger and deeper doped region 120 will require a thicker device layer 108 to maintain a distance 114 between the device region 116 and the gettering layer 102. In some implementations, the gettering layer 102 can also be doped with either carbon, boron, fluorine or any other appropriate impurity. While adding, for example, carbon, boron or fluorine to the gettering layer 102 increases the contaminant trapping (e.g., gettering) properties of the gettering layer, the carbon, boron or fluorine doping also prevents the up-diffusion of oxygen into the device layer 108 from the semiconductor substrate 104. Therefore, the device layer 108 will maintain the reduced oxygen characteristic and, in turn, will be less susceptible to the formation of bulk micro-defects 106 that may cause impurity trapping in the device layer 108.

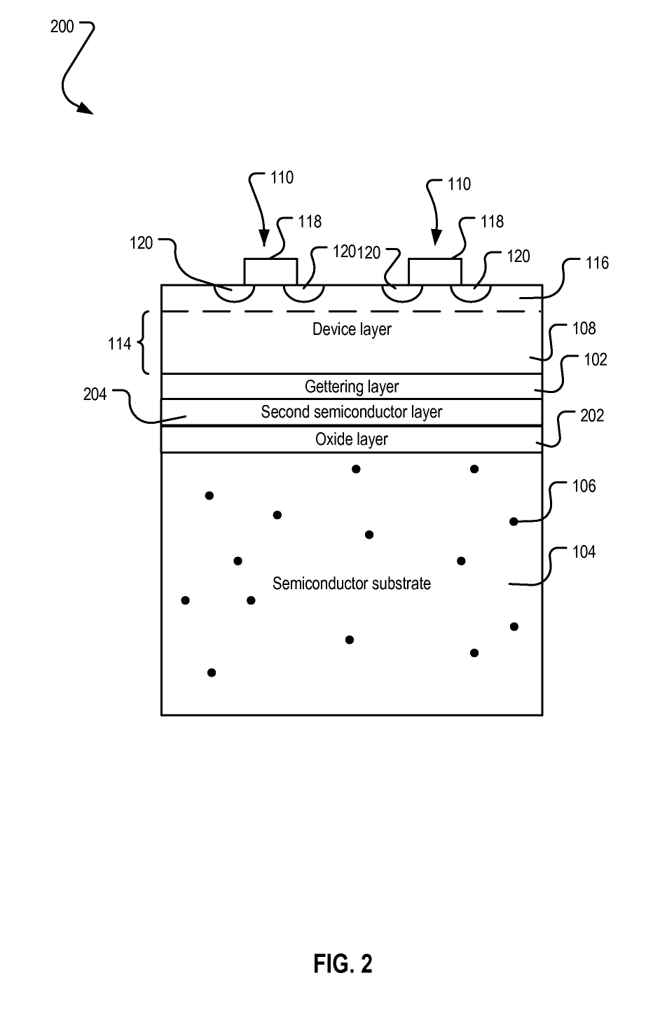

FIG. 2 is a block diagram illustrating another device 200 having a gettering layer 102. The device 200 can have a semiconductor substrate 104 with bulk micro-defects 106 defined therein, a gettering layer 102, a device layer 108 formed on the gettering layer 102, and a device region 116 formed in the device layer 108 that are similar to those common elements described with reference to FIG. 1.

In contrast to the device 100 described with reference to FIG. 1, the device 200, shown in FIG. 2, has an oxide layer 202 formed on the semiconductor substrate 104, and a second semiconductor layer 204 that is formed between the oxide layer 202 and the gettering layer 102. The formation of an oxide layer 202 on a semiconductor substrate 104 in combination with a second semiconductor layer 204 formed on the oxide layer 202, results in a layered substrate that is referred to as a silicon-on-insulator (“SOI”) substrate. Using a SOI substrate further isolates the device region 116 from the semiconductor substrate 104, which increases the performance of high power or high speed devices. Additionally, using a SOI substrate results in greater device isolation that, in turn, reduces current leakage between the devices 110.

The oxide layer 202 can be silicon dioxide or any other appropriate oxide that creates an insulator on the semiconductor substrate 104. The second semiconductor layer 204 can be formed from silicon, silicon germanium, silicon germanium carbide, germanium, germanium carbide, silicon carbide or any other appropriate compounds (e.g., selected from the III/V group or II/VI group.).

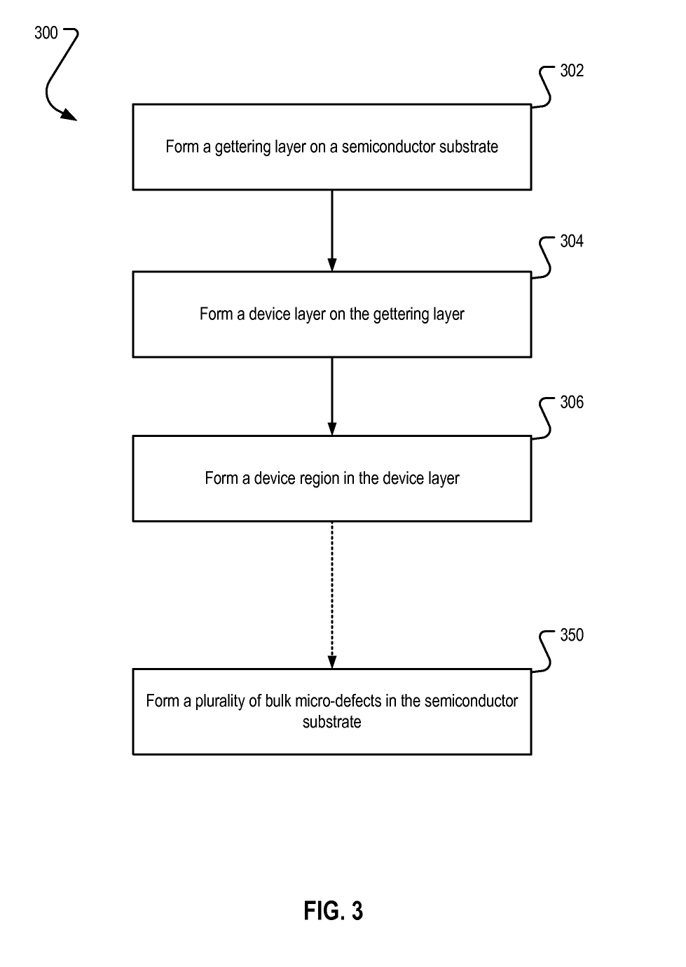

FIG. 3 is a flow chart illustrating a process 300 for manufacturing a device including a gettering layer. The process 300 begins by forming a gettering layer on a semiconductor substrate (302). The gettering layer can be, for example, a film formed from silicon germanium, silicon germanium carbide, silicon carbide, germanium, germanium carbide, or any other appropriate compounds (e.g., selected from the III/V group or II/VI group.). Additionally, the gettering layer can be formed as a strained or partially strained layer. In some implementations, the gettering layer can be doped with either carbon or boron, or a combination of carbon and boron. In other implementations, fluorine or other appropriate impurities can be used to dope the gettering layer. The gettering layer can be formed on a semiconductor substrate formed, for example, from silicon, silicon germanium, silicon germanium, silicon germanium carbide, germanium, germanium carbide, gallium arsenide, or any other appropriate semiconductor substrate (e.g., compounds selected from the III/V group or II/VI group.). Alternatively, the semiconductor substrate can be a SOI substrate.

The process 300 continues by forming a device layer on the gettering layer (304). The device layer can be formed from epitaxially grown silicon, silicon germanium, silicon germanium carbide, germanium, germanium carbide, silicon carbide or any other appropriate compounds (e.g., selected from the II/V group or II/VI group.). In some implementations, the device layer has a thickness that facilitates formation of a device region, while maintaining a distance between the device region and the gettering layer.

The process 300 continues by forming a device region in the device layer (306). The device region 116 is defined, for example, by the depth of the doped regions 120 that form the sources and the drains of the semiconductor devices 110. In some implementations, the device regions 120 are formed having a depth that is less than the thickness of the device layer 108. Limiting the device regions 120 to a depth that is less than the thickness of the device layer 108 maintains a distance 114 between the device region 116 and the gettering layer 120.

In some implementations, the process 300 can optionally form a plurality of bulk micro-defects in the semiconductor substrate (350). The plurality of bulk micro-defects are formed through annealing processes performed during different stages of manufacturing, such as during an annealing stage prior to forming the gettering and device layers. Each annealing process will form additional bulk-micro defects in the semiconductor substrate. In some implementations, the annealing process can continue until a critical concentration (e.g., ˜1E+5/cm³) of bulk micro-defects is achieved. The concentration of bulk micro-defects formed during the annealing processes depends, in part, on the concentrations of interstitial oxygen, vacancies, and boron in the semiconductor substrate.

This written description sets forth the best mode of the invention and provides examples to describe the invention and to enable a person of ordinary skill in the art to make and use the invention. This written description does not limit the invention to the precise terms set forth. Thus, while the invention has been described in detail with reference to the examples set forth above, those of ordinary skill in the art may effect alterations, modifications and variations to the examples without departing from the scope of the invention.

What is claimed is:

1. A method, comprising:
forming a gettering layer on a semiconductor substrate, the gettering layer doped with a dopant that provides enhanced gettering;
forming a device layer on the gettering layer; and
forming a device region in the device layer, the device region having a depth that is less than a depth of the device layer so that a distance is maintained between the device region and the gettering layer.

2. The method of claim 1, wherein forming the gettering layer on the semiconductor substrate, the gettering layer doped with the dopant that provides enhanced gettering comprises forming the gettering layer on the semiconductor substrate, the gettering layer doped with the dopant selected from the group consisting of boron, carbon, and fluorine.

3. The method of claim 1, further comprising forming a plurality of bulk micro-defects in the semiconductor substrate.

4. The method of claim 1, wherein forming the gettering layer comprises depositing a gettering layer selected from the group consisting of silicon germanium, silicon germanium carbide, germanium, and germanium carbide.

5. The method of claim 1, wherein forming the gettering layer on the semiconductor substrate comprises forming the gettering layer on a substrate material selected from the group consisting of silicon, silicon germanium, silicon germanium carbide, germanium, germanium carbide, and gallium arsenide.

6. The method of claim 1, wherein forming the gettering layer on the semiconductor substrate comprises forming the gettering layer on a silicon-on-insulator substrate.

7. The method of claim 1, wherein the forming the device layer comprises epitaxially growing the device layer.

8. The method of claim 1, wherein forming the device layer comprises forming the device layer selected from the group consisting of silicon, silicon germanium, silicon germanium carbide, germanium, germanium carbide, silicon carbide, gallium arsenide, indium phosphide, group III/V semiconductors and group II/VI semiconductors.

9. The method of claim 1, wherein forming the gettering layer comprises forming a strained gettering layer.

10. The method of claim 1, wherein forming the gettering layer comprises forming a partially strained gettering layer.

11. The method of claim 1, further comprising doping the gettering layer with a dopant selected from the group consisting of boron, carbon, and fluorine.

12. The method of claim 1, wherein forming the gettering layer comprises forming a gettering layer having a thickness of 3-500 nanometers.

13. A device, comprising:
a semiconductor substrate;
a gettering layer formed on the semiconductor substrate, the gettering layer doped with a dopant that provides enhanced gettering;
a device layer formed on the gettering layer; and
a device region formed in the device layer, the device region having depth that is less than a depth of the device layer so that a distance is maintained between the device region and the gettering layer.

14. The device of claim 13, wherein the dopant is selected from the group consisting of carbon, boron, and fluorine;

15. The device of claim 13, wherein the semiconductor substrate has a plurality of bulk micro-defects defined therein.

16. The device of claim 13, wherein the gettering layer comprises a gettering film selected from the group consisting of silicon germanium, silicon germanium carbon, silicon carbide, germanium and germanium carbide.

17. The device of claim 13, wherein the semiconductor substrate comprises a substrate material selected from the group consisting of silicon, silicon germanium, silicon germanium carbide, germanium, germanium carbide, gallium arsenide, indium phosphide, group III/V semiconductors and group II/VI semiconductors.

18. The device of claim 13, wherein the device layer comprises an epitaxially grown device region.

19. The device of claim 13, wherein the device layer comprises a film selected from the group consisting of silicon, silicon germanium, silicon germanium carbide, germanium, germanium carbide, and silicon carbide.

20. The device of claim 13, wherein the gettering layer comprises a strained gettering layer.

21. The device of claim 13, wherein the gettering layer comprises a partially strained gettering layer.

22. The device of claim 13, wherein the gettering layer has a thickness of 3-500 nanometers.

23. A system, comprising:
means for gettering attached to a silicon substrate; and
means for maintaining a device region separate from the means for gettering and attached to the means for gettering.
